(19) United States
(12) Patent Application Publication
(10) Pub. No.: US 2014/0321078 A1
(43) Pub. Date: Oct. 30, 2014

(54) DISPLAY DEVICE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: JENG-DA WU, New Taipei (TW); GUANG-FENG OU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/138,429

(22) Filed: Dec. 23, 2013

(30) Foreign Application Priority Data
Apr. 29, 2013 (CN) 2013101550447

(51) Int. Cl. H05K 9/00

(52) U.S. Cl. CPC H05K 9/0007
USPC 361/752

(57) ABSTRACT

A display device includes a top frame, a display, a printed circuit board, and a bottom frame. The top frame includes an anti-EMI cover panel and a securing portion extending from the anti-EMI cover panel. A receiving space is surrounded by the securing portion. The display is mounted in the top frame. The bottom frame includes a bottom panel and a mounting flange extending from the bottom panel. The printed circuit board is mounted on the bottom panel. The mounting flange is received in the receiving spaced and abuts an inner side of the securing portion. The anti-EMI cover panel, the securing portion, and the bottom frame cooperatively define an enclosed space for anti-EMI.

### BACKGROUND

1. Technical Field

The present disclosure generally relates to a display device for anti-EMI.

2. Description of Related Art

Display devices, such as liquid crystal displays (LCDs), are widely used. However, as LCDs become thinner and smaller, electromagnetic interference (EMI) of the display devices becomes more of a problem. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a display device.

FIG. 2 is similar to FIG. 1, but viewed from another aspect.

FIG. 3 is an assembled view of FIG. 1.

FIG. 4 is a cross-sectional view of FIG. 3.

FIG. 5 is a partial and enlarged view of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

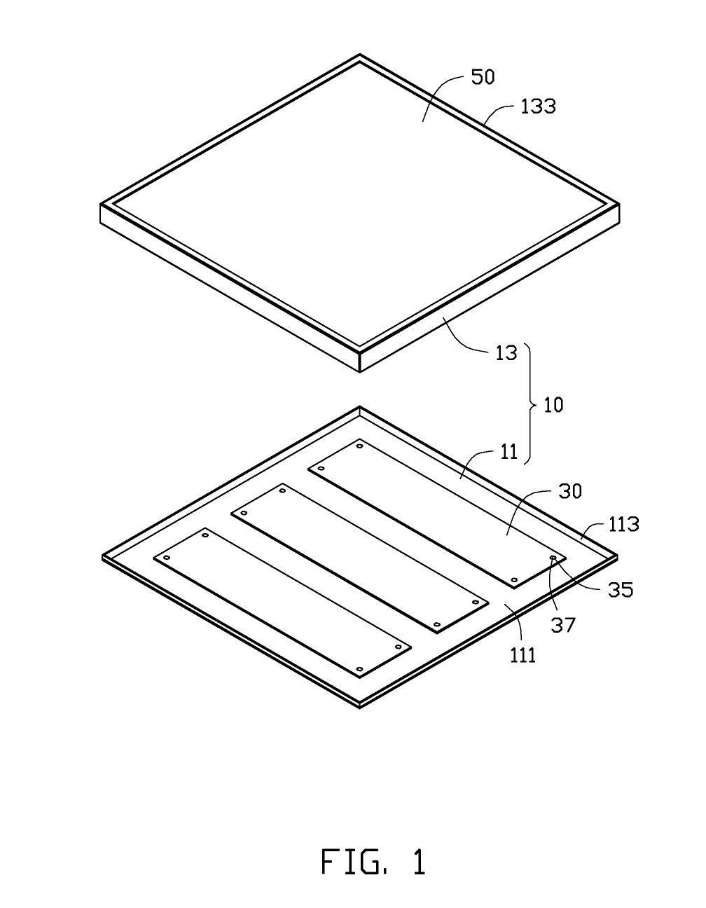

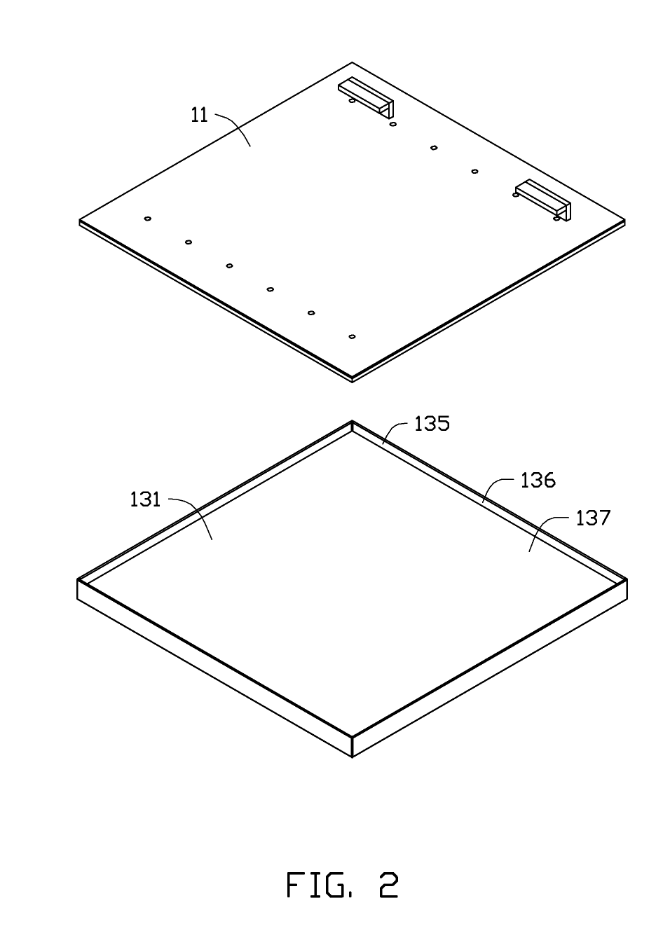

FIGS. 1 and 2 show an embodiment of a display device. The display device includes an enclosure 10, a plurality of printed circuit boards 30, and a display 50.

The enclosure 10 includes a bottom frame 11 and a top frame 13. In one embodiment, the bottom frame 11 is made of metal, and the top frame 13 is made of plastic. The bottom frame 11 includes a bottom panel 111 and a mounting flange 113 extending substantially perpendicularly from sides of the bottom panel 111. The top frame 13 includes an anti-EMI cover panel 131, a mounting portion 133 extending from sides of the anti-EMI cover panel 131, and a securing portion 135 extending from the anti-EMI cover panel 131. The securing portion 135 is substantially perpendicular to the anti-EMI cover panel 131. The anti-EMI cover panel 131 is substantially parallel to the bottom panel 111. A receiving space 137 is cooperatively defined by sides of the securing portion 135 for receiving the bottom frame 11. The securing portion 135 corresponds to the mounting flange 113. An anti-EMI layer 136 is received in an inner space of the securing portion 135.

The mounting portion 133 includes a first resisting portion 1331 and a second resisting portion 1333 substantially parallel to the first resisting portion 1331. The first resisting portion 1331 is substantially parallel to the anti-EMI cover panel 131.

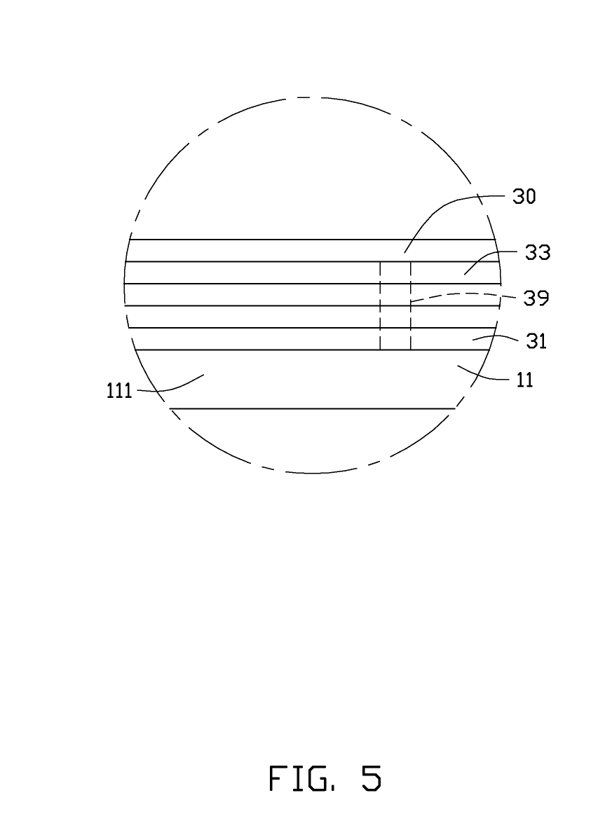

FIG. 5 shows that the printed circuit boards 30 are substantially parallel to the bottom panel 111. Each printed circuit board 30 includes a metal bottom layer 31 and a ground layer 33 substantially parallel to the metal bottom layer 31. The metal bottom layer 31 is connected to the ground layer 33 through a via 39. The metal bottom layer 31 contacts and is substantially parallel to the bottom panel 111. In one embodiment, the metal bottom layer 31 is a copper foil.

Each printed circuit board 30 defines a plurality of securing holes 35. A plurality of fasteners 37 is received through the securing holes 35 correspondingly to secure the printed circuit board 30 to the bottom panel 111.

The display 50 is received to the mounting portion 133 to be mounted in the top frame 13. The display 50 is substantially parallel to the anti-EMI cover panel 131.

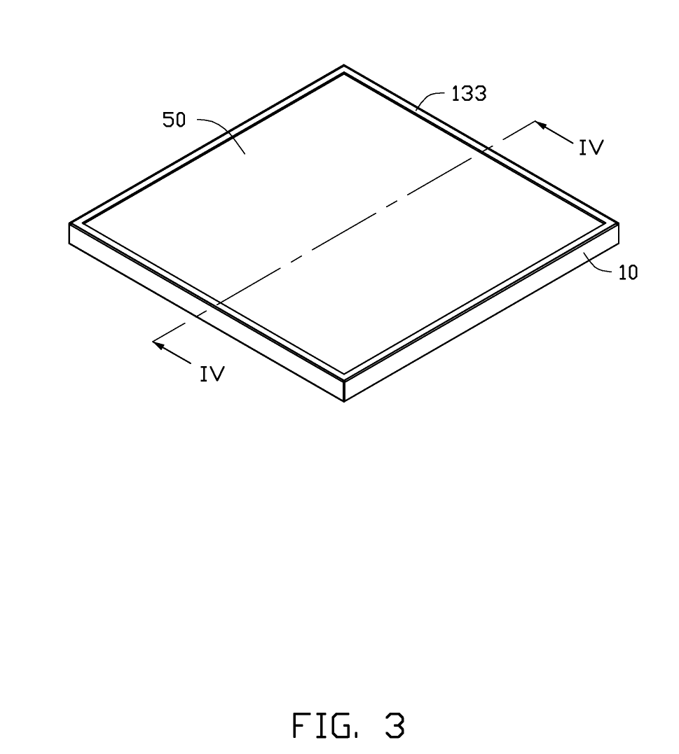

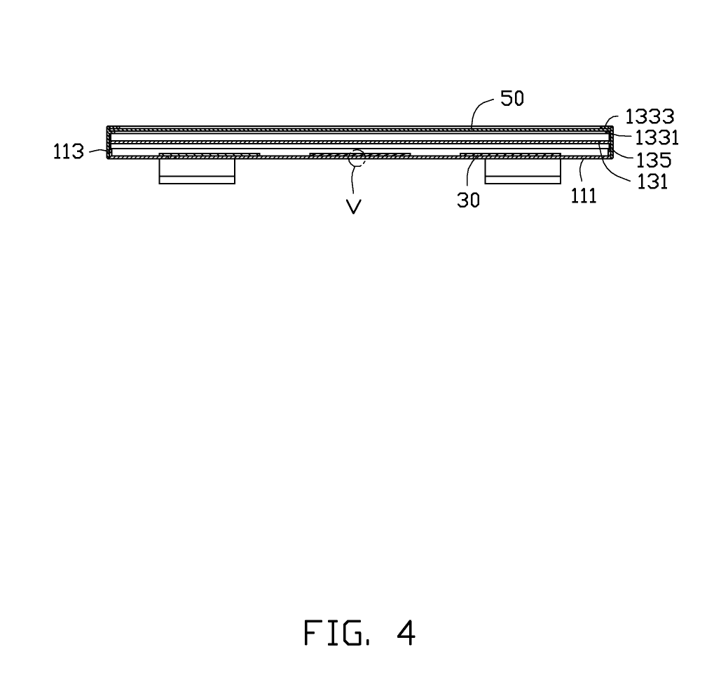

FIGS. 3 and 4 show that in assembly, the mounting flange 113 is received in the receiving space 137 and abuts an inner side of the securing portion 135.

The anti-EMI cover panel 131, the anti-EMI layer 136, and the bottom frame 11 cooperatively define an enclosed space for anti-EMI. The printed circuit board 30 includes a metal bottom layer 31 contacting the bottom panel 111. The metal bottom layer 31 is connected to the ground layer 33 through the via 39, thereby forming a faraday cage for anti-EMI.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A display device comprising:
a top frame, the top frame comprises an anti-EMI cover panel and a securing portion extending from the anti-EMI cover panel, and a receiving space is surrounded by the securing portion;
a display mounted to the top frame;
a printed circuit board; and
a bottom frame, the bottom frame comprises a bottom panel and a mounting flange extending from the bottom panel;
wherein the printed circuit board is mounted on the bottom panel; the mounting flange is received in the receiving spaced and contacts an inner side of the securing portion; and the anti-EMI cover panel, the securing portion, and the bottom frame forms an enclosed space for anti-EMI.

2. The display device of claim 1, wherein the anti-EMI cover panel is substantially parallel to the bottom panel.

3. The display device of claim 1, wherein an anti-EMI layer is placed on the inner side of the securing portion.

4. The display device of claim 1, wherein the bottom panel is made of metal, the printed circuit board comprises a metal bottom layer contacts and is substantially parallel to the bottom panel.

5. The display device of claim 4, wherein the printed circuit board further comprises a ground layer that is substantially parallel to the metal bottom layer, and the ground layer is connected to the metal bottom layer through a via hole.

6. The display device of claim 1, wherein the securing portion is substantially perpendicular to the anti-EMI cover panel.

7. The display device of claim 1, wherein the anti-EMI cover panel is located between the display and the bottom panel.

8. The display device of claim 1, wherein the mounting flange is substantially perpendicular to the bottom panel.

9. The display device of claim 1, wherein the top frame further comprises a mounting portion, the mounting portion comprises a first resisting portion and a second resisting portion substantially parallel to the first resisting portion, and the display is mounted between the first resisting portion and the second resisting portion.

10. The display device of claim 9, wherein the first resisting portion is substantially parallel to the anti-EMI cover panel.
